(19) United States
(12) Patent Application Publication
(10) Pub. No.: US 2026/0234312 A1
(43) Pub. Date: Aug. 13, 2026

(54) PHOTOVOLTAIC ENCAPSULATION FILM COMPOSITION WITH ANTI-PID PERFORMANCE

(71) Applicant: DOW GLOBAL TECHNOLOGIES LLC, Midland, MI (US)

(72) Inventors: Yabin Sun, Shanghai (CN); Wenxin Zhang, Shanghai (CN); Yuyan Li, Shanghai (CN); Brian M. Habersberger, Houston, TX (US)

(21) Appl. No.: 19/156,600

(22) PCT Filed: Mar. 31, 2023
(86) PCT No.: PCT/CN2023/085344

§ 371 Date: Aug. 14, 2025

(51) Int. Cl. C08F 255/04; C08F 4/34; C08F 230/08; H10F 19/80

(52) U.S. Cl. CPC C08F 255/04; C08F 4/34; C08F 230/085; H10F 19/804; H10F 19/807

(57) ABSTRACT

This disclosure is directed to novel encapsulant film compositions that provide anti-PID properties while maintaining good performance for curing, adhesion, volume resistivity. The compositions comprise of: a) a polyolefin polymer; b) an organic peroxide; c) a silane adhesion promotor; and d) a crosslinking co-agent; and e) an anti-PID agent.

### FIELD

This disclosure relates to polyolefin polymer compositions for photovoltaic (PV) encapsulant films. In one aspect, the disclosure relates to polyolefin polymer compositions that resist Potential Induced Degradation (PID). In another aspect, the disclosure relates to PV encapsulant films comprising a polyolefin polymer composition and electronic devices including the same.

### BACKGROUND

The global demand for alternative energy has resulted in large increases in solar panel and PV module production over the last decade. The solar cells (also called PV cells) that convert solar energy into electrical energy are extremely fragile and must be surrounded by a durable encapsulant film. Two main functions of the encapsulant film are to (1) bond the solar cell to the glass coversheet and the backsheet and (2) protect the PV module from environmental stress (e.g., moisture, temperature, shock, vibration, electrical isolation, etc.). Current encapsulant films are primarily made of ethylene vinyl acetate (EVA) because EVA shows a good balance of properties necessary for encapsulant films. EVA is a type of ethylene/unsaturated carboxylic ester copolymer in which the unsaturated carboxylic ester comonomer is a vinyl carboxylate.

Certain polyolefin polymers, such as polyolefin elastomers (POE) that are not ethylene/unsaturated carboxylic ester copolymers, have been identified as an alternative to EVA for forming encapsulant films and have, in comparison to EVA, advantages in, e.g., electric resistivity, wet and heat stability, and weather resistance.

As solar modules are used in different environments, such as high temperature, high humidity and high electrical stress conditions, it has been discovered that the output efficiency of these PV cells made with EVA and POE-based compositions decreases over time. The loss in efficiency caused by electrical stress is known as Potential Induced Degradation (“PID”) and results from leakage current generated due to the difference between the potential of the photovoltaic module frame and the potential of the solar cell. The PID effect may cause power loss of up to 30 percent.

The cause of PID is intertwined with factors that affect photovoltaic module power degradation. However, there is no clear conclusion about the real cause of PID. Some speculate that the PID mechanism in humid, high temperature environments which occur as water vapor enters the module through the edge-sealing silica gel or back plate. The water vapor incursion causes the crystalline silicon photovoltaic module to produce condensation on the surface. This condensation causes the sodium ions in the glass to be released from the glass leading to a negative bias voltage. Under the action of the negative bias voltage, leakage current flows from the cell to the encapsulant adhesive, to the glass surface, to the frame and the bracket, and finally flows to the ground, whereby the output power is attenuated generating the PID phenomenon. Another potential cause of PID is polarization of dielectric layer of solar cell under electrical stress. Higher electrical resistance, volume resistance (“VR”), of encapsulation film reduces electrical field applied on the dielectric layer and its polarization.

In the case where an EVA encapsulant is used it is speculated that negative bias voltage is generated by the hydrolysis of EVA to produce acetic acid. This acetic acid, in turn, reacts with alkali precipitated on the glass surface to produce freely movable sodium ions. Furthermore, EVA has lower electrical resistance. PID, however, is also known issue with POE encapsulants as well if its electrical resistance is not high enough. Consequently, the art recognizes a need for novel encapsulant compositions that provide anti-PID properties while maintaining good performance for curing, and glass adhesion.

### SUMMARY

A composition comprising at least the following:
a) a polyolefin polymer;
b) an organic peroxide;
c) a silane adhesion promotor; and
d) a crosslinking co-agent; and
e) an anti-PID agent.

### DRAWINGS

FIG. 1 is an exploded perspective view of an exemplary photovoltaic module.

### DETAILED DESCRIPTION

Currently, encapsulant films are primarily made of EVA. However, there is strong interest in replacing EVA-based compositions with polyolefin polymer compositions that do not include EVA (e.g., polyolefin elastomers (“POE”) as defined herein) due to certain advantages they can provide for encapsulant films including but not limited to electric resistivity, wet and heat stability, and weather resistance.

The replacement of EVA with POE-based encapsulant films is not without its own challenges. For instance, POE-based encapsulant films require longer lamination time relative to the formation of EVA-based encapsulant films. In WO 2019/000744 A1, the inventors of this application reported POE-based encapsulant films that exhibited a shortening of the time required for soaking POE with a curing package when conventional crosslinking co-agents (e.g., triallyl isocyanurate (“TAIC”)). The compositions of WO 2019/000744 A1 replace traditional crosslinking co-agents with monocyclic organosiloxanes of formula (I): [R¹,R²SiO_{2/2}]ₙ which are further described below. However, the inventors found that once the crosslinking co-agent was switched from TAIC to these monocyclic organosiloxanes, the PID performance becomes unstable. In particular, for some solar cells, the power loss is greater than 5%.

Accordingly, there exists in the prior art a need for novel encapsulant film compositions that provide anti-PID properties while maintaining good performance for curing, adhesion, volume resistivity, etc. To that end, this disclosure provides surprising and unexpected POE-based encapsulant films with anti-PID properties by introducing an anti-PID agent, such as ethyl sorbate or butyl sorbate, or acrylate compounds, like TMTPA, TMPTMA or other acrylate monomers described herein.

### Composition

As discussed above, the invention provides a composition comprising at least the following:
a) a polyolefin polymer;
b) an organic peroxide;
c) a silane adhesion promotor; and
d) a crosslinking co-agent; and
e) an anti-PID agent.

An inventive composition may comprise a combination of two or more embodiments, as described herein.

Each component of an inventive composition may comprise a combination of two or more embodiments as described herein.

### (A) Polyolefin Polymer

The present composition comprises a polyolefin polymer. In certain embodiments, the present composition comprises from 85 wt % to 99.5 wt % (e.g., from 86 wt % to 99.5 wt %, from 87 wt % to 99.5 wt %, from 88 wt % to 99.5 wt %, from 89 wt % to 99.5 wt % from 90 wt % to 99.5 wt %, from 95 wt % to 99.5 wt %, from 97 wt % to 99.5 wt %, from 97.50 wt % to 98.50 wt %, from 97.75 wt % to 98.25 wt %, etc.) of the polyolefin polymer wherein the total weight percent is 100 wt % of the total composition. Said in another way, in certain embodiments, the present composition comprises from 85 wt %, or 88 wt %, or 90 wt %, or 95 wt %, or 97 wt %, or 97.50 wt %, or from 97.75 wt % to 98.25 wt %, or 98.5 wt %, or 99 wt %, or 99.5 wt % of the polyolefin polymer wherein the total weight percent is 100 wt % of the total composition.

In certain embodiments, the polyolefin polymer is a polyolefin elastomer as defined herein. In further embodiments, the polyolefin polymer is a non-polar polyolefin elastomer.

In some embodiments, the polyolefin polymer is an ethylene-based polymer comprising 50 to 100 wt % ethylenic monomeric units, 50 to 0 wt % (C₃-C₂₀) alpha-olefin-derived comonomeric units, and optionally 20 to 0 wt % dienic comonomeric units, wherein the total weight percent is 100 wt % of the polyolefin polymer. The diene used to make the dienic comonomeric units may be 1,3-butadiene, 1,5-hexadiene, 1,7-octadiene, ethylidene norbornene, dicyclopentadiene, or vinyl norbornene.

In some embodiments, the polyolefin polymer is a propylene-based polymer comprising 50 to 100 wt % propylenic monomeric units, 50 to 0 wt % of ethylenic or (C₄-C₂₀) alpha-olefin-derived comonomeric units, and optionally 20 to 0 wt % dienic comonomeric units, wherein the total weight percent is 100 wt % of the polyolefin polymer. The diene used to make the dienic comonomeric units may be 1,3-butadiene, 1,5-hexadiene, 1,7-octadiene, ethylidene norbornene, dicyclopentadiene, or vinyl norbornene.

In some embodiments, the polyolefin polymer is a poly((C₃-C₂₀) alpha-olefin) homopolymer containing 99 to 100 wt % (C₃-C₂₀) alpha-olefin monomeric units or a poly((C₃-C₂₀) alphaolefin) copolymer containing 99 to 100 wt % of at least two different (C₃-C₂₀) alpha-olefin monomeric/comonomeric units.

In certain embodiments, the polyolefin polymer is an ethylene/alpha-olefin interpolymer. Ethylene/alpha-olefin interpolymers can be random or block interpolymers. Block interpolymers include multi-block copolymers and di-block copolymers. Non-limiting examples of suitable ethylene/alpha-olefin interpolymers include ethylene/propylene, ethylene/butene, ethylene/1-hexene, ethylene/1-octene, ethylene/propylene/1-octene, ethylene/propylene/1-butene, and ethylene/butene/1-octene interpolymers. In some embodiments, the ethylene/alpha-olefin interpolymer is an ethylene/alpha-olefin copolymer. Non-limiting examples of suitable ethylene/alpha-olefin copolymers include ethylene/propylene copolymers, ethylene/butene copolymers, ethylene/I-hexene copolymers, and ethylene/1-octene copolymers.

In certain embodiments, the polyolefin polymer is a propylene/alpha-olefin interpolymer, where “alpha-olefin” includes ethylene. In some embodiments, the propylene/alpha-olefin interpolymer is a propylene/alpha-olefin copolymer.

In certain embodiments, the polyolefin polymer has a density from 0.850 g/cc to 0.900 g/cc (e.g., from 0.855 g/cc to 0.900 g/cc, from 0.860 g/cc to 0.900 g/cc, from 0.865 g/cc to 0.900 g/cc, from 0.870 g/cc to 0.890 g/cc, from 0.875 g/cc to 0.890 g/cc, from 0.875 g/cc to 0.885 g/cc, and/or from 0.880 g/cc to 0.885 g/cc) according to ASTM D792. Said in another way, the polyolefin polymer has a density from 0.850 g/cc, or 0.855 g/cc, or 0.860 g/cc, or 0.865 g/cc, or 0.870 g/cc, or 0.875 g/cc, or 0.880 g/cc to 0.885 g/cc, or 0.890 g/cc, or 0.900 g/cc according to ASTM D792.

In certain embodiments, the polyolefin polymer has a melt index (MI) from 1 g/10 min to 100 g/10 min (e.g., from 1 g/10 min to 75 g/10 min, from 1 g/10 min to 50 g/10 min, 1 g/10 min to 45 g/10 min, from 1 g/10 min to 40 g/10 min, from 1 g/10 min to 35 g/10 min, from 1 g/10 min to 30 g/10 min, from 5 g/10 min to 25 g/10 min, from 10 g/10 min to 25 g/10 min, from 15 g/10 min to 25 g/10 min, from 15 g/10 min to 20 g/10 min, and/or from 18 g/10 min to 20 g/10 min) according to ASTM D1238, at 190° C./2.16 kg. Said in another way, in certain embodiments, the polyolefin polymer has a melt index from 1 g/10 min, or 5 g/10 min, or 10 g/10 min, or 15 g/10 min, or 18 g/10 min to 20 g/10 min, or 25 g/10 min, or 30 g/10 min, or 35 g/10 min, or 40 g/10 min, or 45 g/10 min, or 50 g/10 min, or 75 g/10 min, or 100 g/10 min according to ASTM D1238, at 190° C./2.16 kg.

In some embodiments, the polyolefin polymer has a melting point from 40° C. to 125° C. Said in another way, in some embodiments, the polyolefin polymer has a melting point from 40° C., or 45° C., or 50° C., or 55° C. to 60° C., or 65° C., or 70° C., or 80° C., or 90° C., or 95° C., or 100° C., or 110° C., or 120° C., or 125° C.

In some embodiments, the polyolefin polymer has a glass transition temperature (Tg) from −35° C. to −100° C. Said in another way, in some embodiments, the glass transition temperature (Tg) of the polyolefin polymer is from −35° C., or −40° C., or −45° C. or −50° C. to −80° C., or −85° C., or −90° C., or −95° C., or −100° C.

In some embodiments, the polyolefin polymer has a Volume Resistivity ≥1.0×10¹⁴ Ω-cm, or ≥5.0×10¹⁵ Ω-cm, ≥1.0×10¹⁶ Ω-cm, or ≥2.0×10¹⁶ Ω-cm, or ≥3.0×10¹⁶ Ω-cm, or ≥4.0×10¹⁶ Ω-cm, or ≥5.0×10¹⁶ Ω-cm.

In further embodiments, the polyolefin polymer of this disclosure is an ethylene/alpha-olefin interpolymer excluding ethylene/propylene copolymers (e.g., ethylene-propylene rubbers and/or ethylene-propylene terpolymers).

In certain embodiments, the polyolefin polymer is an ethylene/alpha-olefin interpolymer having one, some, or all of the following properties:
(i) a density of 0.850 g/cc, 0.853 g/cc, or 0.855 g/cc, or 0.860 g/cc, or 0.863 g/cc, or 0.865 g/cc, or 0.870 g/cc, or 0.873 g/cc, or 0.875 g/cc, or 0.880 g/cc, or 0.883 g/cc, or 0.885 g/cc, or 0.890 g/cc, or 0.893 g/cc, or 0.895 g/cc, or 0.900 g/cc;
(ii) a melt index of 1 g/10 min, or 5 g/10 min, or 10 g/10 min, or 15 g/10 min, or 18 g/10 min to 20 g/10 min, or 25 g/10 min, or 30 g/10 min, or 35 g/10 min, or 40 g/10 min, or 45 g/10 min, or 50 g/10 min, or 75 g/10 min, or 100 g/10 min; and/or
(iii) a melting point (Tm) of 40° C., or 45° C., or 50° C., or 55° C. to 60° C., or 65° C., or 70° C., or 80° C., or 90° C., or 95° C., or 100° C., or 110° C., or 120° C., or 125° C.;
(iv) a volume resistivity ≥1.0×10¹⁴ Ω-cm, or ≥5.0×10¹⁵ Ω-cm, ≥1.0×10¹⁶ Ω-cm, or ≥2.0×10¹⁶ Ω-cm, or ≥3.0×10¹⁶ Ω-cm, or ≥4.0×10¹⁶ Ω-cm, or ≥5.0×10¹⁶ Ω-cm.

The polyolefin polymer may be a blend or combination of two or more of the foregoing embodiments. The polyolefin polymer may also be blended or diluted with one or more other polymers.

The polyolefin polymer may be made by any suitable process known in the art. Any conventional or hereafter discovered production process for producing polyolefin polymers may be employed for preparing the polyolefin polymer of this disclosure. Exemplary, non-limiting production processes comprise one or more polymerization reactions, such as high pressure polymerization processes or coordination polymerization processes conducted using one or more polymerization catalysts, including but not limited to Ziegler-Natta, chromium oxide, metallocene, constrained geometry, postmetallocene catalysts. Suitable temperatures are from 0° to 250° C., or 30° or 200° C. Suitable pressures are from atmospheric pressure (101 kPa) to 10,000 atmospheres (approximately 1,013 MegaPascals (“MPa”)). In most polymerization reactions, the molar ratio of catalyst to polymerizable olefins (monomer/comonomer) employed is from 10⁻¹²:1 to 10⁻¹:1, or from 10⁻⁹:1 to 10⁻⁵:1.

Non-limiting examples of the polyolefin polymer include ENGAGE™ Polyolefin Elastomers from The Dow Chemical Company, AFFINITY™ Polyolefin Plastomers from The Dow Chemical Company, INFUSE™ Olefin Block Copolymers from The Dow Chemical Company, INTUNE™ PP-based Olefin Block Copolymers from The Dow Chemical Company, EXACT™ resins from Exxon Chemical Company, TAFMER™ resins from Mitsui Chemicals, LUCENE™ resins from LG Chemical, EASTOFLEX™ resins from Eastman Chemical Company, and FLEXOMER™ resins from The Dow Chemical Company.

### (B) Organic Peroxide

The present composition comprises an organic peroxide. In certain embodiments, the present composition comprises from 0.01 wt % to 2 wt % (e.g., from 0.01 wt % to 2 wt %, from 0.05 wt % to 1.5 wt %, and/or from 0.1 wt % to 1.5 wt %, from 0.2 to 1%, from 0.3 to 0.8%, from 0.4 to 0.6%) of an organic peroxide wherein the total weight percent is 100 wt % of the total composition. Said in another way, the present composition comprises from 0.01 wt %, or 0.05 wt %, or 0.1 wt % to 0.2 wt %, or 0.3 wt %, or 0.4 wt %, or 0.5 wt %, or 0.6 wt %, or 1 wt % or 2 wt % of an organic peroxide wherein the total weight percent is 100 wt % of the total composition.

In certain embodiments, the organic peroxide is a molecule containing carbon atoms, hydrogen atoms, and two or more oxygen atoms, and having at least one —O—O— group, with the proviso that when there are more than one —O—O— group, each —O—O— group is bonded indirectly to another —O—O— group via one or more carbon atoms, or collection of such molecules.

The organic peroxide may be a dialkyl peroxide. It may be a monoperoxide of formula R^{O}—O—O—R^{O}, wherein each R^{O} independently is a (C₁-C₂₀) alkyl group or (C₆-C₂₀) aryl group. Each (C₁-C₂₀) alkyl group independently is unsubstituted or substituted with 1 or 2 (C₆-C₁₂) aryl groups. Each (C₆-C₂₀) aryl group is unsubstituted or substituted with 1 to 4 (C₁-C₁₀) alkyl groups. Alternatively, the organic peroxide may be a diperoxide of formula R^{O}—O—O—R—O—O—R^{O}, wherein R is a divalent hydrocarbon group such as a (C₂-C₁₀) alkylene, (C₃-C₁₀) cycloalkylene, or phenylene, and each R^{O} is as defined above.

Non-limiting examples of suitable organic peroxides include dicumyl peroxide; 2,5-dimethyl-2,5-di(t-butyl-peroxy)hexyne-3; 2,5-di-methyl-2,5-di(t-butyl-peroxy)hexane; bis(1,1-dimethylethyl) peroxide; bis(1,1-dimethylpropyl) peroxide; 2,2-di(tert-butylperoxy)butane; di-tert-amyl peroxide (“DTAP”); bis(alpha-t-butyl-peroxyisopropyl) benzene(“BIPB”); isopropylcumyl t-butyl peroxide; t-butylcumylperoxide; butyl 4,4-di(tertbutylperoxy) valerate; di(isopropylcumyl) peroxide; and the like.

The peroxide may be a peroxycarbonates comprising at least one structure below:

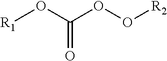

Non-limiting examples of suitable peroxycarbonates type peroxides include isopropyl percarbonate; t-butylperoxy-2-ethylhexyl-carbonate, tert-amylperoxy-2-ethylhexyl carbonate, tert-butylperoxy isopropyl carbonate, tert-butyl peroxy-3,5,5-trimethylhexanoate.

The peroxide may be a diacylperoxide comprising at least one structure below:

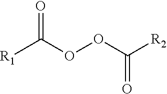

Non-limiting examples of suitable acylperoxide type peroxide includes dilauroyl peroxide; benzoyl peroxide; didecanoyl peroxide;

The peroxide may be a peroxyester comprising at least one structure below:

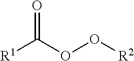

Non-limiting examples of suitable peroxyester type peroxide includes tert-butyl peroxybenzoate, tert-butyl peroxyacetate, tert-amyl peroxybenzoate, tert-butyl peroxy-3,5,5-trimethylhexanoate; tert-butyl peroxyisobutyrate; tert-butyl peroxydiethylacetate; tert-butyl peroxy-2-ethylhexanoate; tert-amyl peroxy-2-ethylhexanoate; 1,1,3,3-tetramethylbutyl peroxy-2-ethylhexanoate; 2,5-Dimethyl-2,5-di(2-ethylhexanoylperoxy) hexane

The peroxide may be a peroxyketals comprising at least one structure below

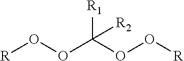

Non-limiting examples of suitable peroxyketals type peroxide includes 1,1-bis(tbutylperoxy)-3,3,5-trimethylcyclohexane; 1,1-di(tert-butylperoxy) cyclohexane; 1,1-di(tert-amylperoxy) cyclohexane

The peroxide may be a cyclic ketone peroxide comprising at least one structure below:

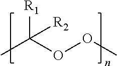

Non-limiting examples of suitable cyclic ketone peroxide includes 3,6,9-triethyl-3,6,9-trimethyl-1,4,7-triperoxonane

Non-limiting examples of suitable commercially available organic peroxides include TRIGONOX® from AkzoNobel and LUPEROX® from ARKEMA.

### (C) Silane Adhesion Promotor

The present composition comprises a silane coupling agent. In certain embodiments, the present composition comprises from 0.01 wt % to 1 wt % (e.g., from 0.05 wt % to 1 wt %, from 0.10 wt % to 1 wt %, from 0.15 wt % to 0.5 wt %, from 0.2 wt % to 0.4 wt %, and/or from 0.25 wt % to 0.3 wt %) of a silane adhesion promotor wherein the total weight percent is 100 wt % of the total composition. Said in another way, the present composition comprises from 0.01 wt %, or 0.05 wt %, or 0.10 wt %, or 0.15 wt %, or 0.20 wt %, or 0.25 wt % to 0.3 wt %, or 0.4 wt %, or 0.5 wt %, or 1 wt % of a silane adhesion promotor wherein the total weight percent is 100 wt % of the total composition.

In some embodiments, the silane adhesion promotor contains at least one alkoxy group. Non-limiting examples of suitable silane adhesion promotor include γ-chloropropyl trimethoxysilane, vinyl trimethoxysilane, vinyl triethoxysilane, vinyl-tris-(β-methoxy)silane, allyltrimethoxysilane, γ-methacryloxypropyl trimethoxysilane, β-(3,4-ethoxy-cyclohexyl)ethyl trimethoxysilane, γ-glycidoxypropyl trimethoxysilane, γ-mercaptopropyltrimethoxysilane, γ-aminopropyl trimethoxysilane, N-β-(aminoethyl)-γ-aminopropyl trimethoxysilane, and 3-(trimethoxysilyl)propylmethacrylate. 3-(trimethoxysilyl)propyl acrylate, tetraethyl orthosilicate, tetramethyl orthosilicate, tetrapropyl orthosilicate. vinyl triisopropoxylsilane, 3-(triethoxysilyl)propyl methacrylate, 3-(triisopropoxysilyl)propyl 2-methylacrylate, vinyl triethoxylsilane, 3-[diethoxy(methyl)silyl]propyl methacrylate.

In some embodiments, the silane adhesion promotor is vinyl trimethoxysilane, 3-(trimethoxysilyl)propylmethacrylate, or 3-(trimethoxysilyl)propyl acrylate.

### (D) Crosslinking Co-Agent

The present composition comprises a crosslinking co-agent comprising a monocyclic organosiloxane of formula (I):

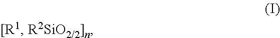

wherein subscript n is an integer greater than or equal to 3; each R¹ is independently a (C₂-C₄) alkenyl; and each R² is independently H, (C₁-C₂₀) alkyl, phenyl, or R¹.

In certain embodiments, the monocyclic organosiloxane of formula (I) is further described by any one of the following limitations: (i) subscript n is 3; (ii) each R¹ is independently a (C₂-C₃) alkenyl; and each R² is independently H, (C₁-C₂) alkyl, or (C₂-C₃) alkenyl; (iii) each R¹ is vinyl; and each R² is independently (C₁-C₂) alkyl; (iv) each R¹ is vinyl; and each R² is methyl; (v) each R¹ is allyl; and each R² is independently (C₁-C₂) alkyl; (vi) each R¹ is allyl; and each R² is methyl.

In certain embodiments, the monocyclic organosiloxane of formula (I) is further described by any one of the following limitations: (i) subscript n is 4; (ii) each R¹ is independently a (C₂-C₃) alkenyl; and each R² is independently H, (C₁-C₂) alkyl, or (C₂-C₃) alkenyl; (iii) each R¹ is vinyl; and each R² is independently (C₁-C₂) alkyl; (iv) each R¹ is vinyl; and each R² is methyl; (v) each R¹ is allyl; and each R² is independently (C₁-C₂) alkyl; (vi) each R¹ is allyl; and each R² is methyl.

In certain embodiments, the monocyclic organosiloxane of formula (I) is further described by any one of the following limitations: (i) subscript n is 5 or 6; (ii) each R¹ is independently a (C₂-C₃) alkenyl; and each R² is independently H, (C₁-C₂) alkyl, or (C₂-C₃) alkenyl; (iii) each R¹ is vinyl; and each R² is independently (C₁-C₂) alkyl; (iv) each R¹ is vinyl; and each R² is methyl; (v) each R¹ is allyl; and each R² is independently (C₁-C₂) alkyl; (vi) each R¹ is allyl; and each R² is methyl.

In certain embodiments, the monocyclic organosiloxane of formula (I) is an alkenyl-functional monocyclic organosiloxane. In certain embodiments, the monocyclic organosiloxane of formula (I) is a cyclic molecule that does not contain carbon or nitrogen in its ring.

In certain embodiments, the monocyclic organosiloxane of formula (I) is a molecule containing a single ring substructure composed of silicon and oxygen atoms disposed in an alternating arrangement; and unsaturated organo groups; and optionally H, saturated or aromatic substituent groups; wherein there are at least two unsaturated organo groups and each of at least two silicon atoms in the ring substructure have at least one unsaturated organo group bonded thereto and wherein after accounting for the unsaturated organo groups and oxygen atoms any remaining valences of the silicon atoms are bonded to the H, saturated or aromatic substituent groups; or collection of such molecules.

The monocyclic organosiloxane of formula (I) may be a monocyclic organosiloxane composed of a 6-membered ring (n=3), an 8-membered ring (n=4), a 10-membered ring (n=5), or a 12-membered ring (n=6). The ring substructure is composed of units of formula (I): [R¹,R²SiO_{2/2}]ₙ (I), wherein subscript n, R¹ and R² are as defined earlier. In each [R¹,R²SiO_{2/2}]ₙ unit, its R¹ and R² groups are bonded to its silicon atom. The units may be designated using conventional organosiloxane shorthand notations simply as D^{R1,R2} such that formula (I) becomes [D^{R1,R2}]ₙ. In this regard, the superscripts R1 and R2 are interchangeable with R¹ and R², respectively. In some aspects, R¹ and R² are the same, alternatively different.

In certain embodiments of the monocyclic organosiloxane of formula (I), R¹ is vinyl and R² is ethyl and the monocyclic organosilxaone of formula (I) is D^{Vi,Et} wherein Vi is vinyl and Et is ethyl; alternatively R¹ is allyl and R² is ethyl and the monocyclic organosiloxane of formula (I) is D^{Allyl,Et}; alternatively R¹ is butenyl (H₂C═C(H)CH₂CH₂—) and R² is ethyl and the monocyclic organosiloxane of formula (I) is D^{Butenyl,Et}. In some aspects, R¹ is vinyl and R² is vinyl and the monocyclic organosiloxane of formula (I) is D^{Vi,Vi}; alternatively R¹ is allyl and R² is allyl and the monocyclic organosiloxane of formula (I) is D^{Allyl,Allyl}; alternatively R¹ is butenyl (H₂C═C(H)CH₂CH₂—) and R² is butenyl and the monocyclic organosiloxane of formula (I) is D^{Butenyl,Butenyl}. In some aspects R¹ is vinyl and R² is phenyl and the monocyclic organosiloxane of formula (I) is D^{Vi,Ph} wherein Ph is phenyl; alternatively R¹ is allyl and R² is phenyl and the monocyclic organosiloxane of formula (I) is D^{Allyl,Ph}; alternatively R¹ is butenyl (H₂C═C(H)CH₂CH₂—) and R² is phenyl and the monocyclic organosiloxane of formula (I) is D^{Butenyl,Ph}. When R² is methyl (CH₃), the unit may be designated more simply as D^{R1} such that formula (I) becomes [D^{R1}]ₙ. In some aspects R¹ is vinyl and R² is methyl and the monocyclic organosiloxane of formula (I) is D^{Vi}; alternatively R¹ is allyl and R² is methyl and the monocyclic organosiloxane of formula (I) is D^{Allyl}; alternatively R¹ is butenyl (H₂C═C(H)CH₂CH₂—) and R² is methyl and the monocyclic organosiloxane of formula (I) is D^{Butenyl}. In some embodiments, the monocyclic organosiloxane of formula (I) is 2,4,6-trimethyl-2,4,6-trivinyl-cyclotrisiloxane, “(D^{Vi})₃” (CAS No. 3901-77-7); 2,4,6,8-tetramethyl-2,4,6,8-tetravinyl-cyclotetrasiloxane, “(D^{Vi})₄” (CAS No. 2554-06-5); or a combination thereof.

In certain embodiments, the crosslinking co-agent of the present composition is composed only of the monocyclic organosiloxane of formula (I).

In certain embodiments, the composition of this disclosure comprises from 0.01 wt % to 5 wt % (e.g., from 0.05 wt % to 4.5 wt %, from 0.1 wt % to 4 wt %, from 0.15 wt % to 3.5 wt %, from 0.2 wt % to 3 wt %, from 0.25 wt % to 2.5 wt %, from 0.3 wt % to 2 wt %, from 0.35 wt % to 1.5 wt %, from 0.4 wt % to 1.25 wt %, from 0.45 wt % to 1 wt %, from 0.5 wt % to 1 wt %, 0.55 wt % to 0.75 wt %, 0.6 wt % to 0.7 wt %, etc.) of the crosslinking co-agent comprising the monocyclic organosiloxane of formula (I), wherein the total weight percent is 100 wt % of the total composition. Said in another way, the composition of this disclosure comprises from 0.01 wt %, or 0.05 wt %, or 0.1 wt %, or 0.15 wt %, or 0.2 wt %, or 0.25 wt %, or 0.3 wt %, or 0.35 wt %, or 0.4 wt %, or 0.45 wt %, or 0.5 wt % or 0.55 wt %, or 0.6 wt % to 0.7 wt %, or 0.75%, 1 wt %, or 1.25 wt %, or 1.5 wt %, or 2 wt %, or 2.5 wt %, or 3 wt %, or 3.5 wt %, or 4 wt %, or 4.5 wt %, or 5 wt % of the crosslinking co-agent comprising the monocyclic organosiloxane of formula (I) wherein the total weight percent is 100 wt % of the total composition. In certain embodiments, the present composition comprises a crosslinking co-agent comprising the monocyclic organosiloxane of formula (I) with the proviso that the composition is free of (i.e., lacks) a phosphazene base. In certain embodiments, the present composition is free of any ring opening catalyst. In further embodiments, when the polyolefin polymer is an ethylene-containing polymer and subscript n (of the monocyclic organosiloxane of formula (I)) is 4, the present composition does not contain 24 wt % or more of, alternatively does not contain 22 wt % or more of, alternatively does not contain 20.0 wt % or more of, alternatively does not contain 15 wt % or more of, alternatively does not contain 10 wt % or more of, alternatively is free of an inorganic filler selected from the group consisting of aluminum oxide, aluminum silicate, calcium silicate, magnesium silicate, silica, titanium dioxide, and mixtures thereof. In further embodiments, the present composition does not contain 20 wt % or more of, alternatively does not contain 15 wt % or more of, alternatively does not contain 10 wt % or more of, alternatively is free of any inorganic filler selected from the group consisting of: solids containing Al, solids containing Ca, solids containing Mg, solids containing Si, solids containing Ti, and mixtures thereof. In further embodiments, the present composition is free of a silsesquioxane, alternatively any siloxane except for the monocyclic organosilxaone of formula (I). In some embodiments, the present composition is free of a silsesquioxane and any one of the abovementioned groups of inorganic fillers.

In certain embodiments, the composition of this disclosure comprises conventional crosslinking co-agents, such as triallyl isocyanurate, triallyl cyanurate, high vinyl polybutadiene.

### (E) Anti-PID Agent

The present composition comprises an anti-PID agent. In certain embodiments, the composition of this disclosure comprises from 0.001 wt % to 1 wt % (e.g., from 0.001 wt % to 0.99 wt %, from 0.001 wt % to 0.96 wt %, from 0.001 wt % to 0.94 wt %, from 0.001 wt % to 0.90 wt %, from 0.002 wt % to 1.0 wt %, from 0.005 wt % to 1 wt %, from 0.01 wt % to 1 wt %, from 0.02 wt % to 1 wt %, from 0.03 wt % to 1 wt %, from 0.04 wt % to 1 wt %, from 0.05 wt % to 1 wt %, from 0.06 wt % to 1 wt %, from 0.07 wt % to 1 wt %, from 0.08 wt % to 1 wt %, from 0.09 wt % to 1 wt %, from 0.1 wt % to 1 wt %, from 0.25 wt % to 1 wt %, from 0.5 wt % to 1 wt %, etc.) of the anti-PID agent wherein the total weight percent is 100 wt % of the total composition. Said in another way, the composition of this disclosure comprises from 0.001 wt %, or 0.003 wt % or 0.005 wt %, or 0.01 wt %, or 0.02 wt %, or 0.03 wt %, or 0.04 wt %, or 0.05 wt %, or 0.06 wt %, or 0.07 wt %, or 0.08 wt %, or 0.09 wt %, or 0.10 wt %, or 0.20 wt %, or 0.30 wt %, or 0.40 wt %, or 0.45 wt %, or 0.50 wt % to 1 wt % of the anti-PID agent wherein the total weight percent is 100 wt % of the total composition.

In some embodiments, the anti-PID agent comprises of at least one structure of formula (II):

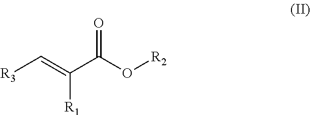

wherein R1, R2 and R3 are each independently a H, methyl, alkyl, alkenyl, linear or branched alkyl or alkenyl, or cyclic, or aromatic, or heteroalkyl, or heteroalkenyl. In some embodiments R2 further comprises of heteroatoms such as Si, S, N, O.

In some embodiments R1 and R3 are each independently an alkyl group selected from the group consisting of: methyl, ethyl, propyl, butyl, pentyl, hexyl, heptyl, octyl, nonyl, and decyl.

In some embodiments R1 and R3 are each independently a cyclic alkyl group selected from the group consisting of: cyclopropyl, cyclobutyl, cyclopentyl, cyclohexyl, cycloheptyl, and cyclooctyl.

In some embodiments, R2 further comprises of an alkyl acrylate or alkyl multi-acrylate such as formula (III) below:

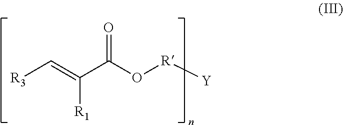

wherein R₁ and R₃ are each independently a H, methyl, alkyl, alkenyl, linear or branched alkyl or alkenyl, or cyclic, or heteroalkyl, or heteroalkenyl.
R′ is selected from a C1-C30 alkylene;
Y is selected from CR₄₋ₙ where n=1 to 4, OR₂₋ₙ where n=1 to 2, NR₃₋ₙ where n=1 to 3, SR₂₋ₙ where n=1 to 2, PR₃₋ₙ where n=1 to 3, PR₅₋ₙ where n=1 to 5, SiR₄₋ₙ where n=1 to 4, a bifunctional C—C core, a phenyl core, a phenyl core substituted with ester, a phenyl core substituted with amide, a tris-isocyanurate core, or a melamine core; and combinations thereof;

In certain embodiments the bifunctional C—C core is selected from the following structures, where each R′ represents the divalent R′ group in formula (III) above:

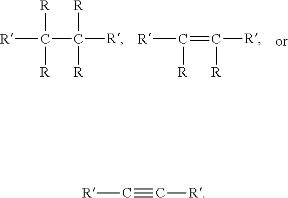

In certain embodiments the phenyl core is selected from the following structures, where each R′ represents the divalent R′ group in formula (III) above:

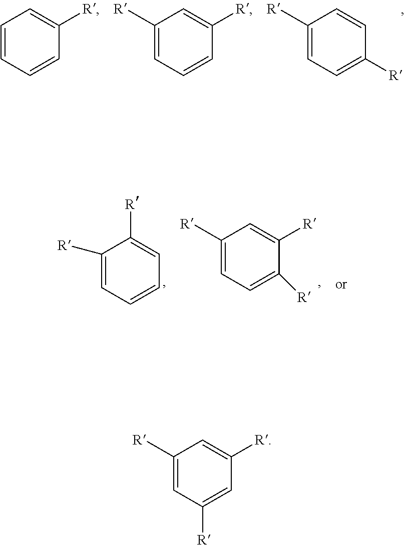

In certain embodiments the phenyl core substituted with ester is selected from the following structures, where each R′ represents the divalent R′ group in formula (III) above:

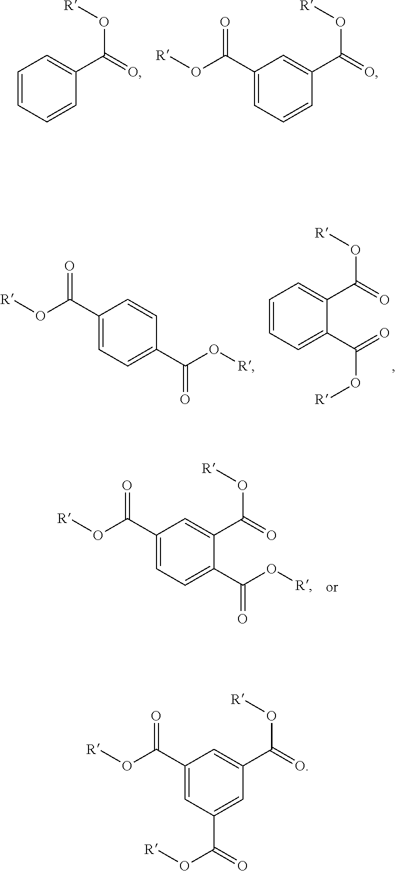

In certain embodiments the phenyl core substituted with amide is selected from the following structures, where each R′ represents the divalent R′ group in formula (III) above:

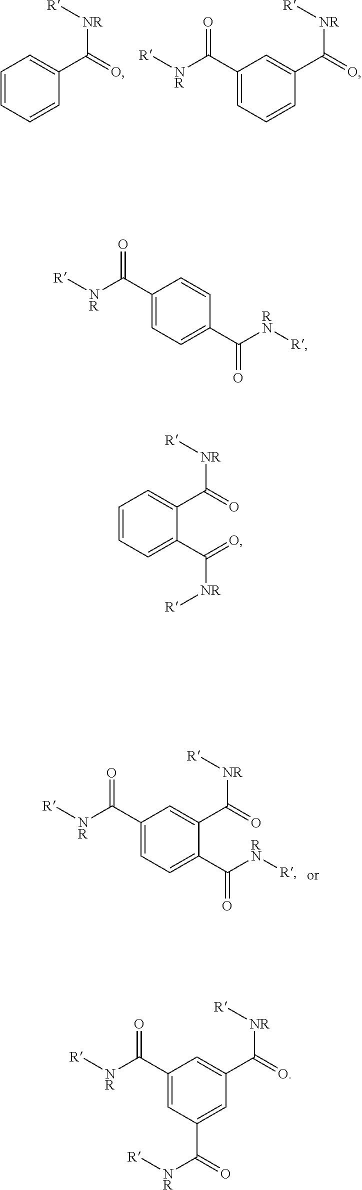

In certain embodiments the tris-isocyanurate core is as follows, where each R′ represents the divalent R′ group in formula (III) above;

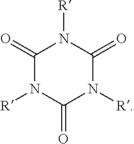

In certain embodiments the melamine core is as follows, where each R′ represents the divalent R′ group in formula (III) above;

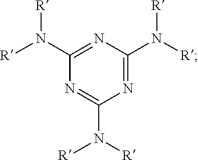

and
wherein each R′ group is independently selected from H, an unsubstituted hydrocarbyl, a substituted hydrocarbyl, an unsubstituted heterohydrocarbyl or a substituted heterohydrocarbyl.

In some embodiments, the present composition comprises of an anti-PID agent comprising an ester of sorbic acid such as methyl sorbate, ethyl sorbate, propyl sorbate, butyl sorbate, and glycidyl sorbate.

Non-limiting examples of suitable anti-PID agents include methyl acrylate, ethyl acrylate, butyl acrylate, cyclopropyl acrylate, ethyl methacrylate, methyl methacrylate, bisphenol-A-glycidyl methacrylate, trimethylolethane trimethacrylate, trimethylolethane triacrylate trimethylolpropane trimethylacrylate (“TMPTMA”), trimethylolpropane triacrylate (“TMPTA”), glycerol triacrylate, pentaerythrityl triacrylate, methyl sorbate, ethyl sorbate, propyl sorbate, butyl sorbate, and glycidyl sorbate. trimethylolpropane triacrylate; trimethylolpropane trimethylacrylate; ethylene glycol dimethacrylate; ethylene glycol diacrylate; diethylene glycol diacrylate; triethylene glycol diacrylate; tetra(ethylene glycol) diacrylate; 1,6-hexanediol diacrylate; 1,6-hexanediol dimethacrylate, neopentanediol dimethacrylate; neopentanediol diacrylate; octadecyl acrylate; butyl acrylate; ethyl acrylate; methyl acrylate; hydroxyl ethyl acrylate; methyl methacrylate; butyl methacrylate; ethyl methacrylate; glycidyl methacrylate; hydroxyl ethyl methacrylate; 2-ethylhexyl acrylate; 2-ethylhexyl methacrylate; dodecyl acrylate; isodecyl acrylate; di(propylene glycol) diacrylate; tri(propylene glycol) diacrylate; lauryl acrylate; alkoylated lauryl acrylate; cyclohexane dimethanol diacrylate; tridecyl methacrylate; tridecyl acrylate; pentaerythritol triacrylate; pentaerythritol tetraacrylate; dipentaerythritol hexaacryate; tris(2-hydroxy ethyl) isocyanurate triacrylate; dipentaery thritol penta acrylate; propoxylated (3) glyceryl triacrylate; zinc diacrylate; zinc dimethacrylate; and esters of sorbic acid.

In some embodiments the anti-PID agent comprises of a monocyclic organosiloxane of formula (I): [R¹,R²SiO_{2/2}]ₙ (I), wherein subscript n is an integer greater than or equal to 3; each R¹ is independently a H₂C═C(R^{1a})—C(═O)—O—(CH₂)ₘ— wherein R^{1a} is H or methyl and subscript m is an integer from 1 to 4; and each R² is independently H, (C₁-C20) alkyl, phenyl, or R¹. Non-limiting examples of suitable crosslinking co-agents includes but is not limited to 2,4,6-trimethyl-2,4,6-trivinyl-cyclotrisiloxane, “(D^{Vi})₃” (CAS No. 3901-77-7); 2,4,6,8-tetramethyl-2,4,6,8-tetravinyl-cyclotetrasiloxane, “(D^{Vi})₄” (CAS No. 2554-06-5); 2,4,6,8,10-pentavinyl-2,4,6,8,10-pentamethylcyclopentasiloxane (CAS No. 17704-22-2); 1,3,5,7,9-pentamethacrylate-1,3,5,7,9-pentamethylcyclopentasiloxane; or a combination thereof.

Surprisingly, the inventors of this application found that these anti-PID agents (such as TMPTMA and TMPTA) can effectively improve the anti-PID performance of the compositions described in WO 2019/000744 A1. Without being bound by theory, it is believed that the silane adhesion promotor (e.g. VMMS) distribution in film is determined by the radical competitions among the different double bonds from different type of crosslinking co-agents. The switching of the crosslinking co-agent from TAIC to monocyclic organosiloxanes described in WO 2019/000744 A1 (such as VD4), possibly leads to high local concentrations of silane adhesion promotors. These areas of higher concentrations are believed to be the root cause of power loss from PID in the solar cell prepared with POE encapsulant films due to more capable of transferring ionic species and reduce the VR of encapsulation film. The additional anti-PID agent, which contain a Michael acceptor group such as an acrylate or sorbate, reduces these localized concentrations of silane adhesion promotor by competing with the silane adhesion promotors for radicals.

In some embodiments the ratio of the silane adhesion promotor to anti-PID agent is ≥1, ≥2.5, ≥5.0, ≥7.5, or ≥10. In some embodiments the ratio of the silane adhesion promotor to anti-PID agent is ≤50, ≤25, ≤15, ≤10 ≤5, or ≤1.

### (F) Optional Additives

In certain embodiments, the present composition includes one or more optional additives. Non-limiting examples of suitable additives include antioxidants, anti-blocking agents, stabilizing agents, colorants, ultra-violet (UV) absorbers or stabilizers, flame retardants, compatibilizers, fillers, hindered amine stabilizers, tree retardants, methyl radical scavengers, scorch retardants, nucleating agents, and processing aids.

In certain embodiments, the hindered amine comprising the structure below:

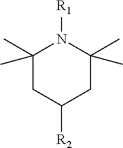

wherein R1 is selected from the group consisting of: hydrogen, methyl, alkyl, alkenyl, linear or branched alkyl or alkenyl, or cyclic, alkoxyl with oxygen connected to nitrogen and R2 is selected from the group consisting of: hydrogen, methyl, alkyl, alkenyl, linear or branched alkyl or alkenyl, or cyclic, further comprise of heteroatoms such as Si, S, N, O.

In certain embodiments, the hindered amine are selected from bis(2,2,6,6,-tetramethyl-4-piperidyl)sebaceate; bis(2,2,6,6,-tetramethyl-4-piperidyl)dibutyl acid ester 4-acetyloxy-2,2,6,6-tetramethylpiperidine; 2,2,6,6-tetramethylpiperidine; 4-hydroxyl-2,2,6,6-tetramethylpiperidine; Bis(1,2,2,6,6-pentamethyl-4-piperidyl) sebacate; bis(2,2,6,6-tetramethyl-1-(octyloxy)-4-piperidinyl) ester; bis(2,2,6,6-tetramethyl-1-(methoxyl)-4-piperidinyl) ester; N,N′-Bis(formyl)-N,N′-bis(2,2,6,6-tetramethyl-4-piperidyl)-1,6-hexanediamine

The optional additives are present in an amount of from greater than zero, or 0.01 wt %, or 0.02 wt %, or 0.04 wt %, or 0.06 wt %, or 0.08 wt % to 0.1% or 0.1 wt % to 1 wt %, or 2 wt %, or 3 wt %, or 5 wt % based on the total weight of the present composition.

### Encapsulant Films

In certain embodiments, this disclosure relates to an encapsulant film comprising a curable composition comprising: (A) a polyolefin polymer, (B) an organic peroxide, (C) a silane adhesion promotor, (D) a silane adhesion promotor co-agent comprising a monocyclic organosiloxane of formula (I) and (E) an anti-PID agent. In some embodiments, the curable composition forms the entirety of the encapsulant film.

In certain embodiments, this disclosure relates to an encapsulant film comprising a crosslinked polymeric composition comprising the reaction product of: (A) a polyolefin polymer, (B) an organic peroxide, (C) a silane adhesion promotor, (D) a crosslinking co-agent comprising a monocyclic organosiloxane of formula (I) and (E) an anti-PID agent. In some embodiments, the crosslinked polymeric composition forms the entirety of the encapsulant film.

In certain embodiments, this disclosure relates to a process for forming an encapsulant film comprising a curable composition or a crosslinked polymeric composition. In certain embodiments, the (A) a polyolefin polymer, (B) an organic peroxide, (C) a silane adhesion promotor, (D) a crosslinking co-agent comprising a monocyclic organosiloxane of formula (I) and (E) an anti-PID agent and any optional additives are pre-mixed, and the pre-mix is added to the (A) polyolefin polymer before or during further processing (e.g., compounding, extruding, molding, etc.) via any method known in the art (e.g., soaking, compounding, etc.). In some embodiments, dry pellets of the (A) polyolefin polymer are soaked in the pre-mix (i.e., curing package composed of the (B) an organic peroxide, (C) a silane adhesion promotor, (D) a crosslinking co-agent comprising a monocyclic organosiloxane of formula (I) and (E) an anti-PID agent and any optional additives) and the soaked pellets are then further processed (e.g., compounded, extruded, molded, etc.). In certain embodiments, the crosslinked polymeric compositions and encapsulant films of this disclosure are formed by film extrusion or compression molding.

In some embodiments, this disclosure relates to a process for forming an encapsulant film, the process comprising (a) soaking a polyolefin polymer with a pre-mix to form a soaked polyolefin polymer, wherein the premix comprises an organic peroxide, a silane adhesion promotor, a crosslinking co-agent comprising the monocyclic organosiloxane of formula (I) and an anti-PID agent. In further embodiments, step (a) is performed at a temperature of from 0° C. to 100° C. (e.g., from 5° C. to 75° C., from 10° C. to 50° C., from 15° C. to 45° C., from 20° C. to 40° C., etc.). In further embodiments, step (a) is performed for a duration (i.e., a soaking time) of from 0 min to 300 min (e.g., from 0 min to 225 min, from 25 min to 200 min, from 50 min to 175 min, from 60 min to 160 min, etc.).

In certain embodiments, the soaked pellets of the (A) polyolefin polymer are converted into film during further processing (e.g., compounding, extruding, casting or molding, etc.). Accordingly, in certain embodiments, the process for forming an encapsulant film further comprises: (2) curing and further processing the soaked polyolefin polymer to form the encapsulant film. In this regard, the temperature during further processing of the soaked polyolefin polymer is higher than the Tm of polymer and at least 20° C. lower than lamination temperature determined by peroxide type, from 80° C., or 90° C. to 100° C., or 105° C., or 110° C., or 115° C., or 120° C., or 125° C., or 130° C., or 140° C., or 150° C., or 160° C., or 170° C.

In further embodiments, it is desirable to avoid or limit curing until other steps, such as lamination with solar cells and two cover sheets or one cover sheet and one backsheet to prepare PV modules, as discussed below. Premature crosslinking and/or premature decomposition of the organic peroxide may result in the encapsulant film having decreased glass adhesion. In other words, the encapsulant film comprising a curable composition remains reactive until lamination, at which point crosslinking is completed and the crosslinked polymeric composition of the encapsulant film becomes a reaction product of the polyolefin polymer, the organic peroxide, the silane adhesion promotor, the crosslinking co-agent comprising the monocyclic organosiloxane of formula (I) and the anti-PID agent. Accordingly, in further embodiments, the process for forming an encapsulant film comprises further processing the soaked polyolefin polymer to form a curable film. Subsequent steps include but are not limited to: curing the curable film to form the encapsulant film, or curing the curable film during a lamination step to form the encapsulant film.

The temperature for further processing the soaked polyolefin polymer may therefore be less than the decomposition temperature of the organic peroxide. In this regard, in some embodiments, the temperature during further processing of the soaked polyolefin polymer is from 80° C., or 90° C. to 100° C., or 110° C., or 120° C.

Curing as discussed herein may be free-radical curing via irradiation of the present composition with a curing effective dose of irradiation and/or heating the present composition at a curing effect temperature thereby forming a crosslinked product. The source of irradiation may be an electron beam, gamma radiation, ultraviolet light, or any combination thereof. In further embodiments, the crosslinking of the present composition occurs without platinum-based catalysts.

The encapsulant film of the present disclosure may have any thickness.

In an embodiment, the encapsulant film is one layer, wherein the single layer is composed of the present composition. In an embodiment, the encapsulant film has two or more layers, wherein at least one layer is composed of the present composition.

### Electronic Devices

An encapsulant film of this disclosure is used to construct an electronic device module. The encapsulant film is used as one or more “skins” for the electronic device, i.e., applied to one or both face surfaces of an electronic device, e.g., as a front encapsulant film or rear encapsulant film, or as both the front encapsulant film and the rear encapsulant film, e.g., in which the device is totally enclosed within the material.

In an embodiment, the electronic device module comprises (i) at least one electronic device, typically a plurality of such devices arrayed in a linear or planar pattern, (ii) at least one cover sheet, and (iii) at least one encapsulant film according to this disclosure. The encapsulant film is between the cover sheet and the electronic device, and the encapsulant film exhibits good adhesion to both the electronic device and the cover sheet.

In an embodiment, the electronic device module comprises (i) at least one electronic device, typically a plurality of such devices arrayed in a linear or planar pattern, (ii) a front cover sheet, (iii) a front encapsulant film, (iv) a rear encapsulant film, and (v) a backsheet, with at least one of the (iii) front encapsulant film and (iv) rear encapsulant film being an encapsulant film of this disclosure. The electronic device is sandwiched between the front encapsulant film and the rear encapsulant film with the two cover sheets or one cover sheet and one backsheet enclosing the front encapsulant film/electronic device/rear encapsulant film unit.

In an embodiment, the cover sheet is glass, acrylic resin, polycarbonate, polyester or fluorine-containing resin. In a further embodiment, the cover sheet is glass.

In an embodiment, the back sheet is a single or multilayer film composed of glass, metal, or a polymeric resin. The back sheet is a film composed of glass or a polymeric resin. In a further embodiment, the back sheet is a multilayer film composed of a fluorine polymer layer and a polyethylene terephthalate layer.

In an embodiment, the electronic device is a solar cell or photovoltaic (PV) cell.

In an embodiment, the electronic device module is a PV module.

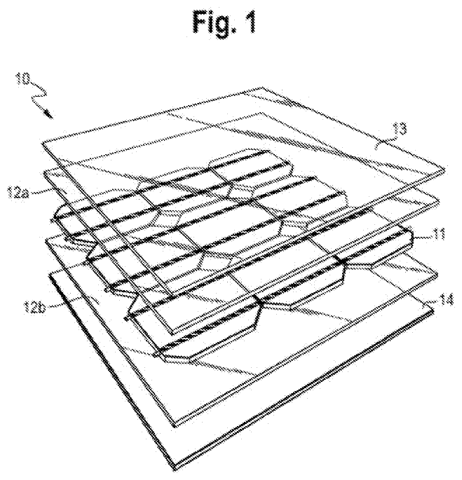

FIG. 1 illustrates an exemplary PV module. The rigid PV module 10 comprises photovoltaic cell 11 (PV cell 11) surrounded or encapsulated by the front encapsulant film 12a and rear encapsulant film 12b. The glass cover sheet 13 covers a front surface of the portion of the front encapsulant film 12a disposed over PV cell 11. The backsheet 14, e.g., a second glass cover sheet or polymeric substrate, supports a rear surface of the portion of the rear encapsulant film 12b disposed on a rear surface of PV cell 11. Backsheet 14 need not be transparent if the surface of the PV cell to which it is opposed is not reactive to sunlight. In this embodiment, the encapsulant films 12a and 12b fully encapsulate PV cell 11. In the embodiment shown in FIG. 1, the front encapsulant film 12a directly contacts the glass cover sheet 13 and the rear encapsulant film 12b directly contacts the backsheet 14. The PV cell 11 is sandwiched between the front encapsulant film 12a and rear encapsulant film 12b such that the front encapsulant film 12a and rear encapsulant film 12b are both in direct contact with the PV cell 11. The front encapsulant film 12a and rear encapsulant film 12b are also in direct contact with each other in locations where there is no PV cell 11.

The encapsulant film of this disclosure can be the front encapsulant film, the rear encapsulant film, or both the front encapsulant film and rear encapsulant film. In an embodiment, the encapsulant film of this disclosure is the front encapsulant film. In another embodiment, the encapsulant film of this disclosure is both the front encapsulant film and the rear encapsulant film.

The encapsulation film of this disclosure can be a single layer film comprising (A) a polyolefin polymer, (B) an organic peroxide, (C) a silane adhesion promotor, (D) a silane adhesion promotor co-agent comprising a monocyclic organosiloxane of formula (I) and (E) an anti-PID agent. Or a coextruded film comprising at least one layer comprising (A) a polyolefin polymer, (B) an organic peroxide, (C) a silane adhesion promotor, (D) a silane adhesion promotor co-agent comprising a monocyclic organosiloxane of formula (I) and (E) an anti-PID agent.

In an embodiment, the encapsulant film(s) of this disclosure are applied to an electronic device by one or more lamination techniques. Through lamination, the cover sheet is brought in direct contact with a first facial surface of the encapsulant film, and the electronic device is brought in direct contact with a second facial surface of the encapsulant film. The cover sheet is brought into direct contact with a first facial surface of the front encapsulant film, the back sheet is brought in direct contact with a second facial surface of the rear encapsulant film, and the electronic device(s) is secured between, and in direct contact with the second facial surface of the front encapsulant film and the first facial surface of the rear encapsulant film.

In an embodiment, the lamination temperature is sufficient to activate the organic peroxide and crosslink the composition, that is, the curable composition comprising the polyolefin polymer, organic peroxide, silane adhesion promotor, crosslinking co-agent, and anti-PID agent. During crosslinking a chemical bond between two or more of the molecular chains of the polyolefin polymer by way of a silane linkage. A “silane linkage” has the structure —Si—O—Si—. Each silane linkage may connect two or more, or three or more, molecular chains of the polyolefin polymer. The silane adhesion promotor also interacts with the surface of the cover sheet to increase adhesion between the encapsulant film and the cover sheet. After lamination, the composition is a reaction product of the polyolefin polymer, the organic peroxide, the silane adhesion promotor agent, the crosslinking co-agent, and the anti-PID agent.

In an embodiment, the lamination temperature for producing an electronic device is from 130° C., or 135° C., or 140° C., or 145° C. to 150° C., or 155° C., or 160° C. In an embodiment, the lamination time is from 8 minutes, or 10 minutes, or 12 minutes, or 15 minutes to 18 minutes, or 20 minutes, or 22 minutes, or 25 minutes.

### Definitions

Any reference to the Periodic Table of Elements is that as published by CRC Press, Inc., 1990-1991. Reference to a group of elements in this table is by the new notation for numbering groups.

For purposes of United States patent practice, the contents of any referenced patent, patent application or publication are incorporated by reference in their entirety (or its equivalent U.S. version is so incorporated by reference) especially with respect to the disclosure of definitions (to the extent not inconsistent with any definitions specifically provided in this disclosure) and general knowledge in the art.

The numerical ranges disclosed herein include all values from, and including, the lower and upper value. For ranges containing explicit values (e.g., 1, or 2, or 3 to 5, or 6, or 7), any subrange between any two explicit values is included (e.g., 1 to 2; 2 to 6; 5 to 7; 3 to 7; 5 to 6; etc.).

Unless stated to the contrary, implicit from the context, or customary in the art, all parts and percents are based on weight and all test methods are current as of the filing date of this disclosure.

Unless stated to the contrary, all test methods are current as of the filing date of this disclosure.

“Blend”, “polymer blend” and like terms mean a composition of two or more polymers. Such a blend may or may not be miscible. Such a blend may or may not be phase separated. Such a blend may or may not contain one or more domain configurations, as determined from transmission electron spectroscopy, light scattering, x-ray scattering, and any other method used to measure and/or identify domain configurations. Blends are not laminates, but one or more layers of a laminate may contain a blend.

“Composition,” as used herein, includes a mixture of materials which comprise the composition, as well as reaction products and decomposition products formed from the materials of the composition.

The terms “comprising,” “including,” “having,” and their derivatives, are not intended to exclude the presence of any additional component, step or procedure, whether or not the same is specifically disclosed. In order to avoid any doubt, all compositions claimed through use of the term “comprising” may include any additional additive, adjuvant, or compound, whether polymeric or otherwise, unless stated to the contrary. In contrast, the term, “consisting essentially of” excludes from the scope of any succeeding recitation any other component, step or procedure, excepting those that are not essential to operability. The term “consisting of” excludes any component, step or procedure not specifically listed. The term “or,” unless stated otherwise, refers to the listed members individual as well as in any combination. Use of the singular includes use of the plural and vice versa.

The term “anti-PID” refers to compositions that resist Potential Induced Degradation or PID.

“Directly contacts” refers to a layer configuration whereby a first layer is located immediately adjacent to a second layer and no intervening layers or no intervening structures are present between the first layer and the second layer.

The term “coagent” means a compound that enhances crosslinking, i.e., a curing coagent. The term “coagent,” “co-agent,” “crosslinking coagent,” and “crosslinking co-agent” are used interchangeably herein. “Conventional coagent” is an acyclic or cyclic compound that enhances crosslinking and contains carbon atoms in its respective backbone or ring substructure. Thus, the backbone or ring substructure of the conventional coagent is based on carbon (carbon-based substructure). In contrast, a silicon-based coagent means an acyclic or cyclic compound that enhances crosslinking and that contains silicon atoms in its respective backbone or ring substructure. The monocyclic organosiloxane of formula (I) is a cyclic silicon-based coagent. Use of a conventional co-agent in a POE-based composition is representative of the state of the art.

The terms “curing” and “crosslinking” are used interchangeably herein to mean forming a crosslinked product (network polymer) without ring opening polymerization.

“Polymer,” as used herein, refers to a polymeric compound prepared by polymerizing monomers, whether of the same or a different type. The generic term polymer thus embraces the term homopolymer (employed to refer to polymers prepared from only one type of monomer, with the understanding that trace amounts of impurities can be incorporated into the polymer structure), and the term interpolymer as defined herein. Trace amounts of impurities, for example, catalyst residues, may be incorporated into and/or within the polymer.

“Interpolymer,” as used herein, refers to polymers prepared by the polymerization of at least two different types of monomers. The generic term interpolymer thus includes copolymers (employed to refer to polymers prepared from two different types of monomers), and polymers prepared from more than two different types of monomers.

“Propylene-based,” “a propylene-based polymer,” “polypropylene,” and like terms refer to a polymer that contains 50 weight percent (wt %) to 100 wt % of polymerized propylene monomers (based on the total amount of polymerizable monomers) and, optionally, may contain at least one comonomer. Such terms include propylene homopolymers and propylene interpolymers (meaning units derived from propylene and one or more comonomers, such as propylene/alpha-olefin interpolymers).

“Ethylene-based,” “an ethylene-based polymer,” “polyethylene,” and like terms refer to a polymer that contains 50 wt % to 100 wt % of polymerized ethylene monomers (based on the total amount of polymerizable monomers) and, optionally, may contain at least one comonomer. Such terms include ethylene homopolymers and ethylene interpolymers (meaning units derived from ethylene and one or more comonomers, such as ethylene/alpha-olefin interpolymers).

“Alpha-olefins” as used herein are hydrocarbon molecules having an ethylenic unsaturation at the primary (alpha) position. For example, “(C₃-C₂₀) alpha-olefins,” as used herein, are hydrocarbon molecules composed of hydrocarbon molecules comprising (i) only one ethylenic unsaturation, this unsaturation located between the first and second carbon atoms, and (ii) at least 3 carbon atoms, or of 3 to 20 carbon atoms. For example, (C₃-C₂₀) alpha-olefin, as used herein, refers to H₂C═C(H)—R, wherein R is a straight chain (C₁-C₁₈) alkyl group. (C₁-C₁₈) alkyl group is a monovalent unsubstituted saturated hydrocarbon having from 1 to 18 carbon atoms. Non-limiting examples of R are methyl, ethyl, propyl, butyl, pentyl, hexyl, heptyl, octyl, nonyl, decyl, undecyl, dodecyl, tridecyl, tetradecyl, pentadecyl, hexadecyl, heptadecyl, and octadecyl. Non-limiting examples of the (C₃-C₂₀) alpha-olefin include propylene, 1-butene, 1-pentene, 1-hexene, 1-octene, 1-dodecene, and mixtures of two or more of these monomers. The (C₃-C₂₀) alpha-olefin may have a cyclic structure such as cyclohexane or cyclopentane, resulting in an alpha-olefin such as 3-cyclohexyl-1-propene (allyl cyclohexane) and vinyl cyclohexane. The (C₃-C₂₀) alpha-olefin may be used as a comonomer with ethylene monomer.

The term “ethylene-containing polymer” means a macromolecule containing repeat units derived from H₂C═CH₂.

“Polyolefin elastomer” or “POE” refer to an elastomeric polymer containing equal to or greater than 50 wt % of polymerized alpha-olefin monomers (including ethylene). “Polyolefin elastomer” include but are not limited to the ethylene-based polymers and propylene-based polymers described herein. As used herein, the term “polyolefin elastomer” excludes ethylene-vinyl acetate (EVA) copolymers.

“Non-polar polymer” and like terms refer to a polymer that does not have a permanent dipole, i.e., the polymer does not have a positive end and a negative end and is void of heteroatoms and functional groups. “Functional group” and like terms refer to a moiety or group of atoms responsible for giving a particular compound its characteristic reactions. Non-limiting examples of functional groups include heteroatom-containing moieties, oxygen-containing moieties (e.g., alcohol, aldehyde, ester, ether, ketone, and peroxide groups), and nitrogen-containing moieties (e.g., amide, amine, azo, imide, imine, nitratie, nitrile, and nitrite groups). A “heteroatom” is an atom other than carbon or hydrogen.

“Photovoltaic cell”, “PV cell” and like terms mean a structure that contains one or more photovoltaic effect materials of any of several inorganic or organic types which are known in the art. For example, commonly used photovoltaic effect materials include one or more of the known photovoltaic effect materials including but not limited to crystalline silicon, polycrystalline silicon, amorphous silicon, copper indium gallium (di)selenide (CIGS), copper indium selenide (CIS), cadmium telluride, gallium arsenide, dye-sensitized materials, and organic solar cell materials. As shown in FIG. 1, PV cells are typically employed in a laminate structure and have at least one light-reactive surface that converts the incident light into electric current. Photovoltaic cells are well known to practitioners in this field and are generally packaged into photovoltaic modules that protect the cell(s) and permit their usage in their various application environments, typically in outdoor applications. PV cells may be flexible or rigid in nature and include the photovoltaic effect materials and any protective coating surface materials that are applied in their production as well as appropriate wiring and electronic driving circuitry.

“Photovoltaic module”, “PV module” and like terms refer to a structure including a PV cell. A PV module may also include a cover sheet, front encapsulant film, rear encapsulant film and backsheet, with the PV cell sandwiched between the front encapsulant film and rear encapsulant film.

“Room temperature” refers to a temperature range of about 20 to about 25° C.

“Further processing,” “further processed,” and like terms refer to manufacturing process steps for polyolefins, including but not limited to compounding, blending, melt blending, extrusion (e.g., film extrusion), kneading, imbibing, injecting, and molding (e.g., injection molding, compression molding, blow molding, etc.). Non-limiting examples of suitable compounding equipment include internal batch mixers (e.g., BANBURY and BOLLING internal mixer) and continuous single or twin-screw mixers (e.g., FARREL continuous mixer, BRABENDER single screw mixer, WERNER and PFLEIDERER twin screw mixers and BUSS kneading continuous extruder). The type of mixer utilized, and the operating conditions of the mixer, can affect properties of the composition such as viscosity, volume resistivity, and extruded surface smoothness.

“Volume resistance” is defined as the ratio of de voltage to current passing between two electrodes (of a specified configuration) that contact opposite sides of the material of the object under test. Volume resistance is reported in ohms.

“Volume resistivity” is defined as the ratio of the de voltage drop per unit thickness to the amount of current per unit area passing through the material. Volume resistivity indicates how readily a material conducts electricity through the bulk of the material. Volume resistivity is expressed in ohm-centimeters (Ω-cm).

Some embodiments of this disclosure will now be described in detail in the following examples.

### EXAMPLES

### Test Methods

Density is measured in accordance with ASTM D792. The result is recorded in grams (g) per cubic centimeter (g/cc or g/cm³).

Glass transition temperature (Tg) is measured according to ASTM D7028.

Melt index (MI) is measured in accordance with ASTM D1238 at 190° C., 2.16 kg and reported in grams per 10 minutes (g/10 min).

Melting point is measured according to ASTM D3418.

The PID test at module level was conducted in accordance with the procedures described in IEC 62804-1.

The initial power output of module samples was recorded with a pulsed solar simulator (Burger PS8/PSS8) with procedures described in IEC 60904. The PID stress process was performed in an environmental chamber under 85° C./85% RH condition. Module samples were connected with a power supply to generate a typical negative bias voltage of 1500V. A standard test takes 96 hours. After stress process, all module samples were retested for power output. The results are compared to the initial measurements to further calculate the power loss.

The IEC standard for power loss after PID test for 96 h is less than 5% for both front and rear side of PV module.

### Materials

The following materials are used to prepare the examples of this disclosure.

POE: an ethylene/octene copolymer having a density of 0.873 g/cc (ASTM D782) and a melt index of 14.0 g/10 min (ASTM D1238 at 190° C., 2.16 kg) available from The Dow Chemical Company. Volume resistance (VR) measured.

TBEC: tert-butylperoxy 2-ethylhexyl carbonate, an organic peroxide available from J&K Scientific Ltd.

TAEC: tert-amylperoxy-2-ethylhexyl carbonate, Lanzhou Additives.

TAIC: triallyl isocyanurate, available from Farida Chemicals Co., Ltd., having the following structure:

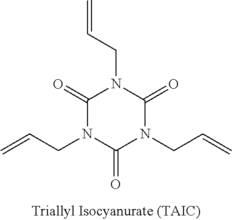 [SMILES: C=CCn1c(=O)n(CC=C)c(=O)n(CC=C)c1=O]

TAC: triallyl cyanurate, available from Sinopharm.

Vinyl-D4: 2,4,6,8-tetramethyl-2,4,6,8-tetravinyl-cyclotetrasiloxane, a co-agent available from Alfa Aser and having the following structure:

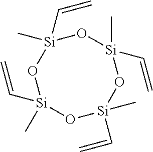 [SMILES: C=C[Si]1(C)O[Si](C)(C=C)O[Si](C)(C=C)O[Si](C)(C=C)O1]

VMMS: 3-(trimethoxysilyl)propylmethacrylate, a silane coupling agent available from Dow Chemical Company

VTMS: Vinyltrimethoxysilane, a silane coupling agent available from Dow Chemical Company

ATM: 3-(Trimethoxysilyl)propyl acrylate, a silane coupling agent available from Dow Chemical Company

TMPTA: Trimethylolpropane triacrylate, commercially available from Farida.

TMPTMA: Trimethylolpropane trimethylacrylate commercially available from Farida.

AMSD: alpha-methyl styrene dimmer(2,4-Diphenyl-4-Methyl-1-Pentene) commercially available from Wuxi Zhiyuan Chemical Company.

Ethyl sorbate commercially available from Sinopharm.

Butyl acrylate (“BA”) commercially available from Sinopharm.

Tinuvin 770 (T770), bis(2,2,6,6,-tetramethyl-4-piperidyl)sebaceate, commercially available from BASF.

The P-type bifacial PERC solar cells were from market.

### Sample Preparation

Soaking: Composition are prepared according to the formulations of Tables 1 and 2, below, by first premixing the polymer pellets were mixed with the curing additives (peroxide, crosslinking coagent and silane coupling agent) in a fluoride HDPE bottle. The soaking process occurred via shaking and an imbibition for 5 hours at 50 C until no liquid residuals were visually seen adhering to the bottle.

Compression Molding: Following soaking, the soaked pellets are compression molded with an embossed mold was used to prepare the film with a thickness of 0.5 mm. Compression molding is performed using a hydraulic press. The compositions are pre-heated at 95° C. under no applied pressure for 3.5 minutes filed by degassing. Subsequently, the compositions are pressed 10 MPa for 2.5 minutes at a temperature of 95° C. Finally, the temperature is cooled to room temperature under 10 MPa pressure within 3.5 minutes.

Lamination: Glass sheets are cut into 4×6 square inch specimens and cleaned using water and then dried before use. The P type bifacial PERC cell, two encapsulant films and two glass specimen are then layered together, and laminated via a PENERGY L036 laminator. The samples were laminated under the conditions: 150° C. for 20 minutes (4 minutes of vacuum process and 16 minutes of pressing to crosslink the encapsulation film). The laminated samples are used for glass adhesion tests. Two identical single cell module samples were prepared for PID test to obtain the average value.

PV glasses and P type PERC bifacial cells used in these examples were acquired from market.

### Formulations

TABLE 1

| | CE- | | CE- | CE- | | | | | | | | | |
|---|---|---|---|---|---|---|---|---|---|---|---|---|---|
| | 1 | IE-1 | 2 | 3 | IE-2 | IE-3 | IE-4 | CE-4 | IE-5 | IE-6 | IE-7 | IE-8 | CE-5 |
| PV8669 | 98.5 | 98.3 | 98.6 | 98.6 | 98.49 | 98.49 | 98.41 | 98.41 | 98.39 | 98.39 | 98.39 | 98.49 | 98.49 |
| TBEC | 0.5 | 0.5 | 0.5 | 0.5 | 0.5 | | 0.5 | 0.5 | 0.5 | 0.5 | 0.5 | 0.5 | 0.5 |
| TAEC | | | | | | 0.5 | | | | | | | |
| VD4 | 0.8 | 0.8 | 0.8 | 0.8 | 0.8 | 0.8 | 0.8 | 0.8 | 0.8 | 0.6 | 0.6 | 0.8 | 0.8 |
| TAC | | | | | | | | | | 0.2 | | | |
| TAIC | | | | | | | | | | | 0.2 | | |
| TMPTA | | 0.2 | | | 0.04 | 0.04 | 0.02 | 0.02 | 0.04 | 0.04 | 0.04 | | |
| TMPTMA | | | | | | | | | | | | 0.04 | |
| AMSD | | | | | | | | | | | | | 0.04 |
| VMMS | 0.2 | 0.2 | 0.1 | 0.1 | 0.1 | 0.1 | 0.1 | 0.2 | 0.2 | 0.2 | 0.2 | 0.1 | 0.1 |
| T770 | | | | 0.07 | 0.07 | 0.07 | 0.07 | 0.07 | 0.07 | 0.07 | 0.07 | 0.07 | 0.07 |
| Total | 100 | 100 | 100 | 100 | 100 | 100 | 100 | 100 | 100 | 100 | 100 | 100 | 100 |

TABLE 2

| | CE-6 | CE-7 | IE-9 | CE-8 | CE-9 | IE-11 | IE-12 | IE-13 | IE-14 |
|---|---|---|---|---|---|---|---|---|---|
| PV8669 | 98.6 | 98.53 | 98.49 | 98.5 | 98.7 | 98.3 | 98.4 | 98.5 | 98.3 |
| TBEC | 0.5 | 0.5 | 0.5 | 0.5 | 0.5 | 0.5 | 0.5 | 0.5 | 0.5 |
| VD4 | 0.8 | 0.8 | 0.8 | 0.8 | 0.8 | 0.8 | 0.8 | 0.8 | 0.8 |
| TAC | | | | | | | | | |
| TAIC | | | | | | | | | |
| Ethyl Sorbate | | | 0.04 | | | | | | |
| BA | | | | | | | | | 0.2 |
| TMPTA | | | | | | | 0.1 | 0.1 | |
| TMPTMA | | | | | | 0.2 | | | |
| ATM | 0.1 | 0.1 | 0.1 | | | | | | |
| VTMS | | | | 0.2 | | | | | |
| VMMS | | | | | | 0.2 | 0.2 | 0.1 | 0.2 |
| T770 | | 0.07 | 0.07 | | | | | | |
| Total | 100 | 100 | 100 | 100 | 100 | 100 | 100 | 100 | 100 |

### Results

TABLE 3

| | CE-1 | IE-1 | CE-2 | CE-3 | IE-2 | IE-3 | IE-4 | CE-4 | IE-5 | IE-6 | IE-7 | IE-8 | CE-5 |
|---|---|---|---|---|---|---|---|---|---|---|---|---|---|
| Power | 3.23 | −0.03 | 3.96 | 4.69 | 0.13 | 0.04 | 1.47 | 3.01 | 0.56 | 0.49 | 0.23 | 0.93 | 4.71 |
| loss of | | | | | | | | | | | | | |
| Front | | | | | | | | | | | | | |
| side, % | | | | | | | | | | | | | |
| Std. | 1.04 | 0.07 | 0.74 | 2.15 | 0.05 | 0.24 | 0.36 | 2.77 | 0.47 | 0.14 | 0.22 | 1.35 | 0.97 |
| dev., % | | | | | | | | | | | | | |
| Power | 9.07 | 0.43 | 12.61 | 14.50 | 0.78 | 0.30 | 3.10 | 7.03 | 1.21 | 1.26 | 0.72 | 3.67 | 14.56 |
| loss of | | | | | | | | | | | | | |
| Rear | | | | | | | | | | | | | |
| side, % | | | | | | | | | | | | | |
| Std. | 2.32 | 0.13 | 3.96 | 6.481 | 0.21 | 0.04 | 1.18 | 6.95 | 0.69 | 0.19 | 0.66 | 3.45 | 4.03 |
| dev., % | | | | | | | | | | | | | |

As shown in Table 3, the comparison between CE-1 and IE-1 suggests TMPTA improved the anti-PID performance significantly, the power loss after the 96 h PID test decreased from around 9% for rear side and 3.2% for front side to lower than 0.5%.

A comparison of CE-2 and CE-3 with IE-2 to IE-5 also suggests a significant improvement in anti-PID performance with the presence of TMPTA. However, CE-4 suggests that low loadings of TMPTA compared to VMMS, e.g. VMMS/TMPTA=10, cannot reduce the power loss lower than 5%. Further, IE-8 suggests that TMPTMA can also improve anti-PID performance compared to CE-2. CE-5 suggesting that no anti-PID performance is exhibited by AMSD.

TABLE 4

| | CE-6 | CE-7 | IE-9 | CE-8 | CE-9 | IE-11 | IE-12 | IE-13 | IE-14 |
|---|---|---|---|---|---|---|---|---|---|
| Power | 3.57 | 3.29 | 0.38 | 2.57 | 0.40 | 0.49 | 0.44 | 0.27 | 0.66 |
| loss of | | | | | | | | | |
| Front | | | | | | | | | |
| side, % | | | | | | | | | |
| Std. | 2.59 | 0.20 | 0.01 | 0.23 | 0.05 | 0.49 | 0.60 | 0.17 | 0.88 |
| dev., % | | | | | | | | | |
| Power | 10.08 | 9.93 | 1.40 | 5.49 | 0.44 | 1.65 | 2.06 | 0.46 | 2.29 |
| loss of | | | | | | | | | |
| Rear | | | | | | | | | |
| side, % | | | | | | | | | |
| Std. | 6.45 | 1.46 | 0.72 | 0.33 | 0.08 | 1.81 | 1.63 | 0.51 | 1.56 |
| dev., % | | | | | | | | | |

As shown in Table 4, ethyl sorbate also significantly reduces the PID loss (e.g. CE-6/CE-7 vs IE-9). Further, CE-9 in Table 4 suggests that in the absence of a silane adhesion promoter, VD4 itself does not cause PID loss.

Finally, IE-15 and IE-16 suggest very low PID loss was achieved by TMPTA in the presence of conventional coagents such as TAIC and TAC.

In summary, sorbate and acrylate based compounds reduce the power loss after PID test.

1. A curable composition for forming an encapsulant film, wherein the composition comprises:
A) a polyolefin polymer;
B) an organic peroxide;
C) a silane adhesion promotor; and
D) a crosslinking co-agent, a monocyclic organosiloxane of formula (I): [R¹,R²SiO_{2/2}]ₙ (I), wherein subscript n is an integer greater than or equal to 3; each R¹ is independently a (C₂-C₂₀) alkenyl and combinations thereof; and
E) an anti-PID agent comprising at least one structure as formula (II): 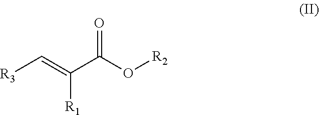
wherein R1, R2 and R3 are each independently a H, methyl, alkyl, alkenyl, linear or branched alkyl or alkenyl, or cyclic, or heteroalkyl, or heteroalkenyl.

2. The curable composition of claim 1 wherein the polyolefin polymer further comprises of an ethylene/α-olefin copolymer having a volume resistivity (VR) greater than 1.0×10¹⁴ Ω-cm at 23° C., density from 0.85 to 0.92 g/cm³. MI from 1 to 50 g/10 min. at 190° C.

3. The curable composition of claim 1 wherein the peroxide is selected from the group consisting of: isopropyl percarbonate; t-butylperoxy-2-ethylhexyl-carbonate; tert-amylperoxy-2-ethylhexyl carbonate, tert-butylperoxy isopropyl carbonate; tert-butyl peroxy-3,5,5-trimethylhexanoate; 1,1-bis(tbutylperoxy)-3,3,5-trimethylcyclohexane; 1,1-di(tert-butylperoxy)cyclohexane; 1,1-di(tert-amylperoxy)cyclohexane; dicumyl peroxide; di-tert-amyl peroxide (“DTAP”); bis(alpha-t-butyl-peroxyisopropyl) benzene; and combinations thereof.

4. The curable composition of claim 1 wherein the crosslinking co-agent is selected from the group consisting of: 2,4,6-trimethyl-2,4,6-trivinyl-cyclotrisiloxane; 2,4,6,8-tetramethyl-2,4,6,8-tetravinyl-cyclotetrasiloxane; 2,4,6,8,10-pentavinyl-2,4,6,8,10-pentamethylcyclopentasiloxane; 1,3,5,7,9-pentamethacrylate-1,3,5,7,9-pentamethylcyclopentasiloxane; or a combination thereof.

5. The curable composition of claim 1 wherein the anti-PID agent is selected from the group consisting of: trimethylolethane trimethacrylate, trimethylolethane triacrylate, trimethylolpropane triacrylate;trimethylolpropane trimethylacrylate; ethylene glycol dimethacrylate; ethylene glycol diacrylate; diethylene glycol diacrylate; triethylene glycol diacrylate; tetra(ethylene glycol) diacrylate; 1,6-hexanediol diacrylate; 1,6-hexanediol dimethacrylate, neopentanediol dimethacrylate; neopentanediol diacrylate; octadecyl acrylate; butyl acrylate; ethyl acrylate; methyl acrylate; hydroxyl ethyl acrylate; methyl methacrylate; butyl methacrylate; ethyl methacrylate; glycidyl methacrylate; hydroxyl ethyl methacrylate; 2-ethylhexyl acrylate; 2-ethylhexyl methacrylate; dodecyl acrylate; isodecyl acrylate; di(propylene glycol) diacrylate; tri(propylene glycol) diacrylate; lauryl acrylate; alkoylated lauryl acrylate; cyclohexane dimethanol diacrylate; tridecyl methacrylate; tridecyl acrylate; pentaerythritol triacrylate; pentaerythritol tetraacrylate; dipentaerythritol hexaacryate; tris(2-hydroxy ethyl) isocyanurate triacrylate; dipentaery thritol penta acrylate; propoxylated (3) glyceryl triacrylate; zinc diacrylate; zinc dimethacrylate; ester of sorbic acid like ethyl sorbate; a monocyclic organosiloxane of formula (I): [R¹,R²SiO_{2/2}]ₙ (I), wherein subscript n is an integer greater than or equal to 3; each R¹ is independently a H₂C═C(R^{1a})—C(═O)—O—(CH₂)ₘ— wherein R^{1a} is H or methyl and subscript m is an integer from 1 to 4; and each R² is independently H, (C₁-C₂₀) alkyl, phenyl, or R¹; and combinations thereof.

6. The composition of claim 1, wherein the composition further comprises:
A) 85 wt % to 99.5 wt % of the polyolefin polymer;
B) from 0.01 wt % to 2 wt % of the organic peroxide;
C) from 0.01 wt % to 1 wt % of the silane adhesion promotor;
D) from 0.01 wt % to 5 wt % of the silane crosslinking co-agent; and
E) from 0.001 wt % to 1 wt % of the anti-PID agent.

7. The composition of claim 1, wherein the anti-PID agent of formula II comprised in anti-PID agent is further described by any one of limitations (i) to (ii): (i) R1 is H, methyl, ethyl, propyl, or butyl; and (ii) R3 is H, methyl, ethyl, propyl, butyl, vinyl or substituted vinyl.R2 further comprises of an alkyl acrylate or alkyl multi-acrylate such as formula (III) below: 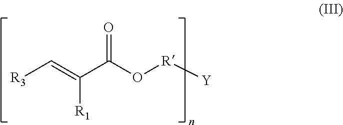
wherein R1 and R3 are each independently a H, methyl, alkyl, alkenyl, linear or branched alkyl or alkenyl, or cyclic, or heteroalkyl, or heteroalkenyl.
R′ is selected from a C1-C30 alkylene;
Y is selected from the group consisting of: CR₄₋ₙ where n=1 to 4, OR₂₋ₙ where n=1 to 2, NR₃₋ₙ where n=1 to 3, SR₂₋ₙ where n=1 to 2, PR₃₋ₙ where n=1 to 3, PR₅₋ₙ where n=1 to 5, SiR₄₋ₙ where n=1 to 4, a bifunctional C—C core, a phenyl core, a phenyl core substituted with ester, a phenyl core substituted with amide, a tris-isocyanurate core, a melamine core, or combinations thereof.

8. The composition of claim 1, wherein the anti-PID agent is selected from the group consisting of: methyl acrylate, ethyl acrylate, butyl acrylate, cyclopropyl acrylate, ethyl methacrylate, methyl methacrylate, bisphenol-A-glycidyl methacrylate, 1,6-hexanediol diacrylate, 1,6-hexanediol dimethacrylate, trimethylolethane trimethacrylate, trimethylolethane triacrylate, trimethylolpropane trimethylacrylate, trimethylolpropane triacrylate, glycerol triacrylate, pentaerythrityl triacrylate, and combinations thereof.

9. An encapsulant film comprising a crosslinked polymeric composition comprising the reaction product of:
A) a polyolefin polymer;
B) an organic peroxide;
C) a silane adhesion promotor; and
D) a crosslinking co-agent, a monocyclic organosiloxane of formula (I): [R¹,R²SiO_{2/2}]ₙ (I), wherein subscript n is an integer greater than or equal to 3; each R¹ is independently a (C₂-C₂₀) alkenyl and combinations thereof; and
E) an anti-PID agent comprising at least one structure as formula (II): 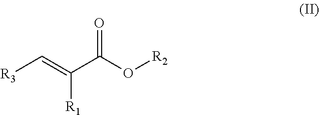
wherein R1, R2 and R3 are each independently a H, methyl, alkyl, alkenyl, linear or branched alkyl or alkenyl, or cyclic, or heteroalkyl, or heteroalkenyl.

10. The encapsulant film of claim 10 comprising a crosslinked polymeric composition comprising the reaction product of:
A) 85 wt % to 99.5 wt % of the polyolefin polymer;
B) from 0.01 wt % to 2 wt % of the organic peroxide;
C) from 0.01 wt % to 1 wt % of the silane adhesion promotor;
D) from 0.01 wt % to 5 wt % of the crosslinking co-agent; and
E) from 0.001 wt % to 1 wt % of the anti-PID agent.

11. The encapsulant film of claim 10, wherein the polyolefin polymer is an ethylene/alpha-olefin copolymer comprising a density of from 0.850 g/cc to 0.890 g/cc (ASTM D792) and a melt index of from 1.0 g/10 min to 50.0 g/10 min (ASTM D1238, at 190° C./2.16 kg).

12. The encapsulant film of claim 10, wherein the anti-PID agent is selected from the group consisting of: methyl acrylate, ethyl acrylate, butyl acrylate, cyclopropyl acrylate, ethyl methacrylate, methyl methacrylate, bisphenol-A-glycidyl methacrylate, 1,6-hexanediol diacrylate, 1,6-hexanediol dimethacrylate, trimethylolethane trimethacrylate, trimethylolethane triacrylate, trimethylolpropane trimethylacrylate, trimethylolpropane triacrylate, glycerol triacrylate, pentaerythrityl triacrylate, and combinations thereof.

13. The multi-layer encapsulation film comprising at least one layer composed of the composition in claim 1.

14. The encapsulant film of claim 10, wherein the encapsulant film has a power loss after PID on a front side and a back side of less than than 5%.

15. An electronic device module comprising:
A) an electronic device
B) a cover sheet, and
C) the encapsulant film of claim 10.

16. The electronic device in claim 15 is from p-type bifacial PERC (Passivated Emitter and Rear Cell) and n-type TOPCon (tunnel oxide passivated contact).
